(19) United States
(12) Patent Application Publication
(10) Pub. No.: US 2026/0331205 A1
(43) Pub. Date: Oct. 22, 2026

(54) BUILT-IN SELF-TEST FOR MEMORY DEVICES

(71) Applicant: Micron Technology, Inc., Boise, ID (US)

(72) Inventor: Aaron P. BOEHM, Boise, ID (US)

(21) Appl. No.: 19/468,269

(22) Filed: Feb. 3, 2026

Related U.S. Application Data
(60) Provisional application No. 63/782,808, filed on Apr. 3, 2025.

(51) Int. Cl. G11C 29/44; G11C 29/30; G11C 29/52

(52) U.S. Cl. CPC G11C 29/4401; G11C 29/30; G11C 29/52

(57) ABSTRACT

Implementations described herein relate to a built-in self-test for memory devices. In some implementations, a memory device may detect an error associated with one or more memory cells based on a built-in self-test. The memory device may identify a row address associated with the error. The memory device may store the row address in a register space, wherein the row address is retired based on the row address stored in the register space.

### CROSS-REFERENCE TO RELATED APPLICATION

This Patent Application claims priority to U.S. Provisional Patent Application No. 63/782,808, filed on Apr. 3, 2025, entitled “BUILT-IN SELF-TEST FOR MEMORY DEVICES,” and assigned to the assignee hereof. The disclosure of the prior Application is considered part of and is incorporated by reference into this Patent Application.

### TECHNICAL FIELD

The present disclosure generally relates to memory devices, memory device operations, and, for example, to a built-in self-test for memory devices.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1 is a diagram illustrating an example system capable of a built-in self-test for memory devices.

FIG. 2 is a diagrammatic view of an example memory device.

FIG. 3 is a diagram illustrating an example associated with a built-in self-test for memory devices.

FIG. 4 is a flowchart of an example method associated with a built-in self-test for memory devices.

### DETAILED DESCRIPTION

DRAM is a type of volatile memory used in electronic devices that stores data temporarily while a system is running. DRAM may lose data when power is turned off. DRAM may require constant refreshing to maintain stored data. DRAM may provide a higher storage capacity as compared to SRAM. DRAM may be slower but more affordable than SRAM. Different types of DRAM may include synchronous DRAM (SDRAM), double data rate (DDR) SDRAM, or high bandwidth memory (HBM). SDRAM may be synchronized with a system clock for better performance. DDR SDRAM may transfer data twice per clock cycle. HBM may be an advanced DRAM for high-performance computing and artificial intelligence (AI) applications.

DRAM may employ on-die error code correction (ECC) to correct single bit errors in an array. A DRAM chip may be organized into multiple arrays, where each array may include memory cells in a grid (e.g., rows and columns), word lines, bit lines, and sense amplifiers. The on-die ECC may be performed without host (system) knowledge of the correction, which may become an issue in safety-critical applications. For example, as single bit errors accumulate without any permanent mitigation due to the host (system) being unaware of the correction, an uncorrectable error may occur. The uncorrectable error may occur when two or more bit errors occur in the same ECC codeword. In other words, single bit errors may be corrected without host (system) knowledge, but the single bit errors may accumulate and potentially lead to multi-bit errors, which may not be correctable. The multi-bit errors may especially be an issue for safety-critical applications because the multi-bit errors may not be correctable.

DRAM may employ a built-in self-test to enable self-diagnosis and fault detection during manufacturing and system operation. The built-in self-test may help to identify defective memory cells, interconnect issues, and timing-related failures without requiring external testing equipment. The built-in self-test may be useful for DRAM due to high-density memory chips (e.g., defects may increase when a DRAM cell size is decreased), manufacturing variability (e.g., small imperfections in silicon may cause random bit failures), reliability requirements, and post-manufacturing testing.

When DRAM is equipped with the built-in self-test, a host may run a built-in self-test cycle. The DRAM may identify errors and perform a hard repair when redundant resources exist. Redundant resources may be finite and may become exhausted over time. When the redundant resources are no longer available, further repairs may no longer be possible. Additionally, hard repair sequences may take an inordinate amount of time, which may not be afforded with certain applications. In these cases, the host may prioritize host-side mitigation instead of the built-in self-test. Additionally, the host may not be provided with information needed to map around failed DRAM pages. For example, the host may not be provided with an address of a row that has been repaired using the built-in self-test. The host may have an ability to retire (e.g., isolate and disable) memory pages that have failures at a memory management unit (MMU) level, but the host may be unable to identify page addresses that contain such failures, so the host may be unable to retire relevant pages. As a result, an inability for the host to obtain information from the built-in self-test may affect a memory page mapping and/or a memory page retiring, thereby degrading an overall system performance.

In some implementations, a memory device, such as a DRAM device, may start a built-in self-test. The built-in self-test may be initiated for the memory device by a host associated with the memory device. The memory device may detect an error associated with one or more memory cells based on the built-in self-test. The error may be associated with a single bit error. The single bit error may be a permanent error based on a physical defect associated with the one or more memory cells. The memory device may determine, based on a mode register setting, that a repair sequence associated with the built-in self-test is bypassed, where the repair sequence may be associated with repairing a row address. The memory device may determine whether a repair is available for the row address. The memory device may store the row address in a register space. The row address associated with the error may be stored in the register space in accordance with an error reporting. The row address may be stored in the register space based on the repair not being available for the row address. The register space may be accessible to the host. The host may read the row address in the register space. The host may retire the row address based on an inclusion of the row address in the register space. The memory device may resume a normal operation after the row address is retired, where the normal operation may not be associated with the built-in self-test. The row address may be retired to prevent the row address from becoming associated with an uncorrectable error. By retiring the row address, the row address may no longer be used by the memory device. In other words, the host may not perform read or write operations with respect to that row address. Further, the host may perform a mapping function based on the row address. For example, DRAM may be mapped, accessed, and/or managed in a manner that accounts for failed row addresses.

In some implementations, the host may utilize information (e.g., row address information) associated with the built-in self-test to identify pages associated with errors, and the host may determine to retire such pages. The host may retire the pages at a system level. The host may retire pages that are associated with single bit errors and/or pages that are associated with uncorrectable errors. For example, the host may retire pages associated with permanent single bit errors to minimize a probability of uncorrectable errors occurring due to the permanent single bit errors accumulating in a codeword. A page that is associated with a permanent single bit error (e.g., an error due to a physical defect in memory) may be more prone to turning into a page that is associated with an uncorrectable error because the permanent single bit error may potentially turn into a multi-bit error, in contrast to a page that is not associated with any permanent single bit errors. Thus, an ability for the host to obtain, from the memory device, the information associated with the built-in self-test may allow the host to retire certain pages that are more prone to uncorrectable errors, thereby improving an overall system performance.

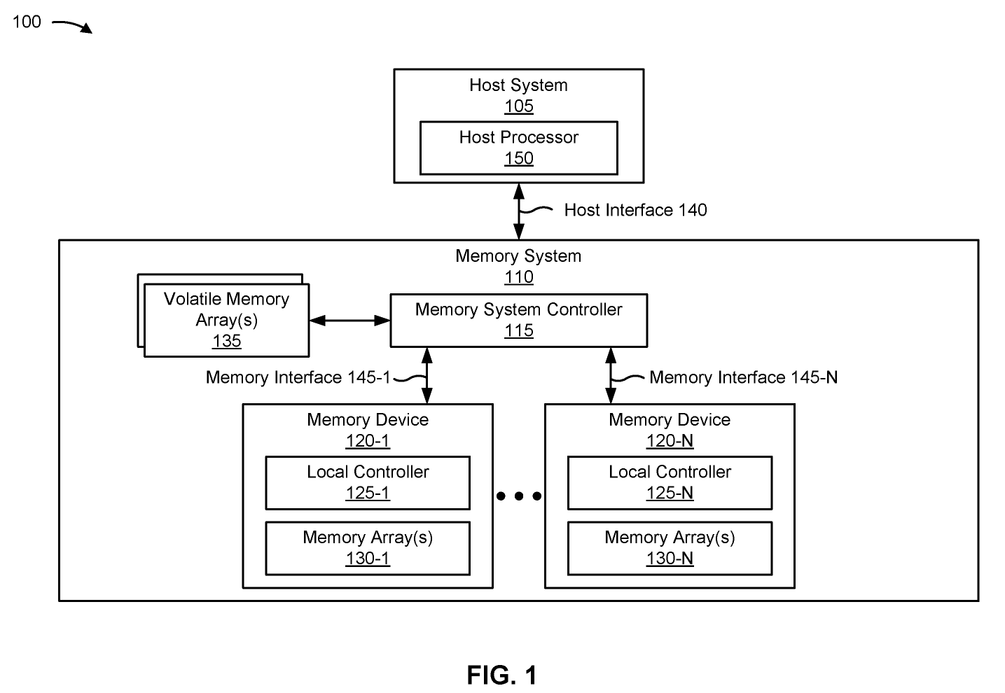

FIG. 1 is a diagram illustrating an example system 100 capable of a built-in self-test for memory devices. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N ≥ 1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N ≥ 1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a DDR interface, and/or a DIMM interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some implementations, one or more systems, devices, apparatuses, components, and/or controllers of FIG. 1 may be configured to detect an error associated with one or more memory cells based on a built-in self-test; identify a row address associated with the error; and store the row address in a register space, wherein the row address is retired based on the row address stored in the register space.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

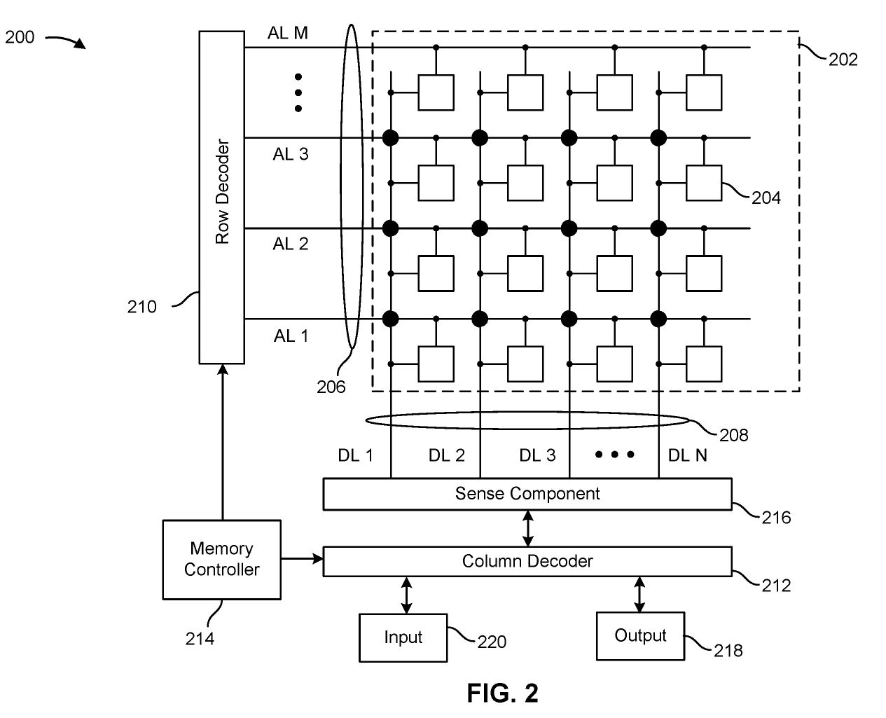

FIG. 2 is a diagrammatic view of an example memory device 200. The memory device 200 may include a memory array 202 that includes multiple memory cells 204. A memory cell 204 is programmable or configurable into a data state of multiple data states (e.g., two or more data states). For example, a memory cell 204 may be set to a particular data state at a particular time, and the memory cell 204 may be set to another data state at another time. A data state may correspond to a value stored by the memory cell 204. The value may be a binary value, such as a binary 0 or a binary 1, or may be a fractional value, such as 0.5, 1.5, or the like. A memory cell 204 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 204 by activating or selecting the appropriate access line 206 (shown as access lines AL 1 through AL M) and digit line 208 (shown as digit lines DL 1 through DL N). An access line 206 may also be referred to as a “row line” or a “word line,” and a digit line 208 may also be referred to a “column line” or a “bit line.” Activating or selecting an access line 206 or a digit line 208 may include applying a voltage to the respective line. An access line 206 and/or a digit line 208 may comprise, consist of, or consist essentially of a conductive material, such as a metal (e.g., copper, aluminum, gold, titanium, or tungsten) and/or a metal alloy, among other examples. In FIG. 2, each row of memory cells 204 is connected to a single access line 206, and each column of memory cells 204 is connected to a single digit line 208. By activating one access line 206 and one digit line 208 (e.g., applying a voltage to the access line 206 and digit line 208), a single memory cell 204 may be accessed at (e.g., is accessible via) the intersection of the access line 206 and the digit line 208. The intersection of the access line 206 and the digit line 208 may be called an “address” of a memory cell 204.

In some implementations, the logic storing device of a memory cell 204, such as a capacitor, may be electrically isolated from a corresponding digit line 208 by a selection component, such as a transistor. The access line 206 may be connected to and may control the selection component. For example, the selection component may be a transistor, and the access line 206 may be connected to the gate of the transistor. Activating the access line 206 results in an electrical connection or closed circuit between the capacitor of a memory cell 204 and a corresponding digit line 208. The digit line 208 may then be accessed (e.g., is accessible) to either read from or write to the memory cell 204.

A row decoder 210 and a column decoder 212 may control access to memory cells 204. For example, the row decoder 210 may receive a row address from a memory controller 214 and may activate the appropriate access line 206 based on the received row address. Similarly, the column decoder 212 may receive a column address from the memory controller 214 and may activate the appropriate digit line 208 based on the column address.

Upon accessing a memory cell 204, the memory cell 204 may be read (e.g., sensed) by a sense component 216 to determine the stored data state of the memory cell 204. For example, after accessing the memory cell 204, the capacitor of the memory cell 204 may discharge onto its corresponding digit line 208. Discharging the capacitor may be based on biasing, or applying a voltage, to the capacitor. The discharging may induce a change in the voltage of the digit line 208, which the sense component 216 may compare to a reference voltage (not shown) to determine the stored data state of the memory cell 204. For example, if the digit line 208 has a higher voltage than the reference voltage, then the sense component 216 may determine that the stored data state of the memory cell 204 corresponds to a first value, such as a binary 1. Conversely, if the digit line 208 has a lower voltage than the reference voltage, then the sense component 216 may determine that the stored data state of the memory cell 204 corresponds to a second value, such as a binary 0. The detected data state of the memory cell 204 may then be output (e.g., via the column decoder 212) to an output component 218 (e.g., a data buffer). A memory cell 204 may be written (e.g., set) by activating the appropriate access line 206 and digit line 208. The column decoder 212 may receive data, such as input from input component 220, to be written to one or more memory cells 204. A memory cell 204 may be written by applying a voltage across the capacitor of the memory cell 204.

The memory controller 214 may control the operation (e.g., read, write, re-write, refresh, and/or recovery) of the memory cells 204 via the row decoder 210, the column decoder 212, and/or the sense component 216. The memory controller 214 may generate row address signals and column address signals to activate the desired access line 206 and digit line 208. The memory controller 214 may also generate and control various voltages used during the operation of the memory array 202.

As indicated above, FIG. 2 is provided as an example. Other examples may differ from what is described with respect to FIG. 2.

DRAM is a type of volatile memory used in electronic devices that stores data temporarily while a system is running. DRAM may lose data when power is turned off. DRAM may require constant refreshing to maintain stored data. DRAM may provide a higher storage capacity as compared to SRAM. DRAM may be slower but more affordable than SRAM. Different types of DRAM may include SDRAM, DDR SDRAM, or HBM. SDRAM may be synchronized with a system clock for better performance. DDR SDRAM may transfer data twice per clock cycle. HBM may be an advanced DRAM for high-performance computing and AI applications.

DRAM may store each bit of data in a capacitor within a memory cell. The memory cell may include the capacitor and a transistor. The capacitor may store an electrical charge representing the bit (1 or 0). The transistor may act as a switch to control access to the capacitor. When writing to DRAM, a memory controller may send a row and column address to locate the memory cell (e.g., a target memory cell). The transistor in the memory cell may open, which may allow charge to flow into the capacitor. A charged capacitor may represent 1, and an uncharged capacitor may represent 0. The transistor may close, thereby storing the data in the capacitor. When reading data from DRAM, the memory controller may select the row and column address. The transistor may open, which may allow stored charge to flow into a sense amplifier. The sense amplifier may detect if the charge level represents a 1 or a 0. The charge may be restored (refreshed) in the capacitor since reading discharges the capacitor. The data may be sent to a processor for use. Over a period of time, the charge in the capacitor may leak, which may require a periodic refresh cycle to maintain the data. A refresh process may be handled by the memory controller.

DRAM may support on-die ECC to improve data reliability. On-die ECC may involve detecting and correcting memory errors within a DRAM chip itself before the data is sent to the memory controller. As DRAM manufacturing moves to smaller process nodes, memory cells may become more susceptible to errors due to leakage, interference, and lower voltage margins. Traditional ECC memory requires an extra memory chip for error detection and correction. On-die ECC may perform correction within the DRAM chip, which may reduce the need for external error correction. When data is written to DRAM, an ECC algorithm may generate parity bits and store the parity bits with the data in the DRAM chip. When the data is read back, ECC logic within the DRAM chip may check for errors. When a single bit error is found, the error may be corrected immediately before the data is sent to the memory controller. When a multi-bit error occurs, depending on an ECC scheme, the multi-bit error may be flagged as an uncorrectable error. On-die ECC may be handled internally by the DRAM and may not require support from the processor or the memory controller.

DRAM may employ on-die ECC to correct single bit errors in an array. A DRAM chip may be organized into multiple arrays, where each array may include memory cells in a grid (e.g., rows and columns), word lines, bit lines, and sense amplifiers. The on-die ECC may be performed without host (system) knowledge of the correction, which may become an issue in safety critical applications. For example, as single bit errors accumulate without any permanent mitigation due to the host (system) being unaware of the correction, an uncorrectable error may occur. The uncorrectable error may occur when two or more bit errors occur in the same ECC codeword. In other words, single bit errors may be corrected without host (system) knowledge, but the single bit errors may accumulate and potentially lead to multi-bit errors, which may not be correctable. The single bit errors may be due to a permanent fault. A single bit error may be combined with an event that also causes a bit error, which may result in a multi-bit error. The multi-bit errors may be an issue, especially for safety-critical applications, because the multi-bit errors may not be correctable.

DRAM may employ a built-in self-test to enable self-diagnosis and fault detection during manufacturing and system operation. The built-in self-test may help to identify defective memory cells, interconnect issues, and timing-related failures without requiring external testing equipment. The built-in self-test may be useful for DRAM due to high-density memory chips (e.g., defects may increase when a DRAM cell size is decreased), manufacturing variability (e.g., small imperfections in silicon may cause random bit failures), reliability requirements, and post-manufacturing testing.

The built-in self-test may be embedded in the memory controller or the DRAM chip. The built-in self-test may involve a pattern generator. Test patterns may be generated to stress memory cells. The built-in self-test may involve an address generator. Specific rows and columns may be selected for testing. The built-in self-test may involve a read/write controller. Test data may be written and results may be verified. The built-in self-test may involve an error detector and logger. Faulty memory cells may be detected and failures may be logged. In one example, the built-in self-test may use resources, such as spare rows and columns of memory cells.

When DRAM is equipped with the built-in self-test, a host may run a built-in self-test cycle. The DRAM may identify errors and perform a hard repair when redundant resources exist. Redundant resources may be finite and may become exhausted over time. When the redundant resources are no longer available, further repairs may no longer be possible. Additionally, hard repair sequences may take an inordinate amount of time, which may not be afforded with certain applications. In these cases, the host may prioritize host-side mitigation instead of the built-in self-test. Additionally, the host may not be provided with information associated with repaired bit errors. For example, the host may not be provided with an address of a row that has been repaired using the built-in self-test. The host may have an ability to retire (e.g., isolate and disable) memory pages that have permanent failures at an MMU level, but the host may be unable to identify page addresses that contain such failures, so the host may be unable to retire relevant pages. As a result, an inability for the host to obtain the information from the built-in self-test may affect a memory page mapping and/or a memory page retiring, thereby degrading an overall system performance.

In some implementations, a memory device, such as a DRAM device, may start a built-in self-test. The built-in self-test may be initiated for the memory device by a host associated with the memory device. The memory device may detect an error associated with one or more memory cells based on the built-in self-test. The error may be associated with a single bit error. The single bit error may be a permanent error based on a physical defect associated with the one or more memory cells. The memory device may determine, based on a mode register setting, that a repair sequence associated with the built-in self-test is bypassed, where the repair sequence may be associated with repairing the row address. The memory device may determine whether a repair is available for the row address. The memory device may identify a row address associated with the error. The memory device may store the row address in a register space. The row address associated with the error may be stored in the register space in accordance with an error reporting. The row address may be stored in the register space based on the repair not being available for the row address. The register space may be accessible to the host. The host may read the row address in the register space. The host may retire the row address based on an inclusion of the row address in the register space. The memory device may resume a normal operation after the row address is retired, where the normal operation may not be associated with the built-in self-test. The row address may be retired to prevent the row address from becoming associated with an uncorrectable error. By retiring the row address, the row address may no longer be used by the memory device. In other words, the host may not perform read or write operations with respect to that row address.

In some implementations, the host may utilize information (e.g., row address information) associated with the built-in self-test to identify pages associated with errors, and the host may determine to retire such pages. The host may retire the pages at a system level. The host may retire pages that are associated with single bit errors and/or pages that are associated with uncorrectable errors. For example, the host may retire pages associated with permanent single bit errors to minimize a probability of uncorrectable errors occurring due to the permanent single bit errors accumulating in a codeword. A page that is associated with a permanent single bit error (e.g., an error due to a physical defect in memory) may be more prone to turning into a page that is associated with an uncorrectable error because the permanent single bit error may potentially turn into a multi-bit error, in contrast to a page that is not associated with any permanent single bit errors. Thus, an ability for the host to obtain, from the memory device, the information associated with the built-in self-test may allow the host to retire certain pages that are more prone to uncorrectable errors, thereby improving an overall system performance.

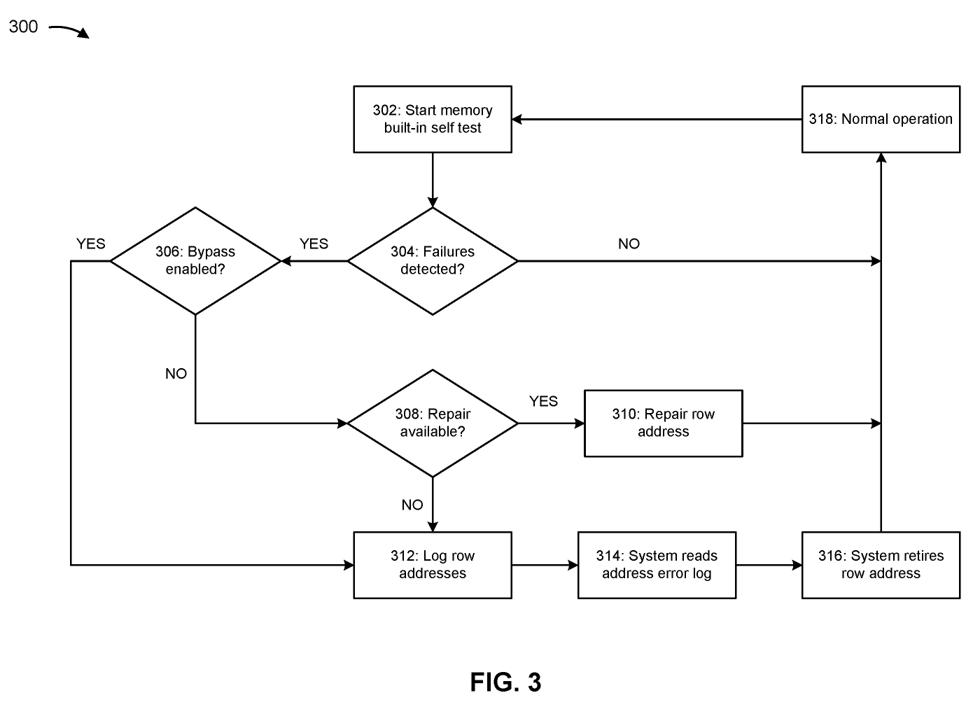

FIG. 3 is a diagram of an example 300 associated with a built-in self-test for memory devices. The operations described in connection with FIG. 3 may be performed by the memory system 110 and/or one or more components of the memory system 110, such as the memory system controller 115, one or more memory devices 120, and/or one or more local controllers 125.

As shown by reference number 302, a host (e.g., a controller) associated with the memory system 110 may initiate a built-in self-test, which may be implemented by a DRAM. The built-in self-test may be a memory built-in self-test (MBIST). The built-in self-test may enable self-diagnosis and fault detection during system operation. The built-in self-test may help to identify defective DRAM cells without requiring external testing equipment.

As shown by reference number 304, the DRAM may determine whether a failure is detected based on the built-in self-test. The failure may be associated with a DRAM cell. The DRAM cell may be associated with a single bit error, which may be a permanent single bit error (e.g., due to a physical defect with the DRAM cell). The DRAM cell may be associated with a multi-bit error, which may be classified as an uncorrectable error. When no failure is detected, the host may perform a normal operation (as shown by reference number 318). The normal operation may not include the built-in self-test.

As shown by reference number 306, when the failure is detected, the DRAM may determine whether a bypass is enabled. The DRAM may determine whether to bypass a repair sequence associated with the built-in self-test. The DRAM may determine to bypass the repair sequence based on a mode register setting. In one example, the repair sequence may be able to be bypassed all of the time. In another example, the repair sequence may be able to be bypassed when repair resources are consumed (e.g., fully consumed or consumed up to a certain threshold).

As shown by reference number 308, when the bypass is not enabled, the DRAM may determine whether a repair is available. The DRAM may determine a memory bank associated with a failed row address. The DRAM may determine whether any row repair remains. In one example, the DRAM may determine whether repair resources are available for mitigating the failure. The repair resources may be subject to a finite amount, such that the repair may no longer be available when the repair resources are mitigated. The repair resources may include redundant DRAM cells (e.g., redundant rows and/or columns of DRAM cells), which may be used to repair the failure.

As shown by reference number 310, when the repair is available, the DRAM may repair a row address, where the row address may be associated with the failure. The row address may be associated with one or more failed DRAM cells. The DRAM may repair the row address using the repair resources. After the row address is repaired, the DRAM may perform the normal operation (as shown by reference number 318).

As shown by reference number 312, when the bypass is enabled or when the repair is not available, the DRAM may log (or store) a row address in a register. The row address may be associated with a previously failed row address. In other words, the row address may be associated with the row address that was repaired. The DRAM may log the failed row address (or multiple addresses) to a register space, such as a user accessible register space. The register space may be accessible to the host, which may allow the host to determine the row address.

As shown by reference number 314, the host may read the register space containing the failed row address. The host may read the register space that contains the row address that was repaired, which may allow the host to be notified of the row address that was repaired by the DRAM. Without the register space, the DRAM may perform the repair but the host may be unaware of the row address that was repaired. By the DRAM logging the failed row address to the register space and the host being configured to read the register space, the host may be notified regarding a specific DRAM cell (or multiple DRAM cells) that was/were repaired due to failure.

As shown by reference number 316, the host may retire the row address indicated in the register space. The host may retire (e.g., isolate and disable) the row address, which may be based on the failure associated with the row address. For example, the row address may be associated with a permanent failure (e.g., a permanent single bit error), which may increase a likelihood of the row address becoming associated with a multi-bit, uncorrectable error. In this case, the host may retire the row address so that that particular row address is not used in the future, which may prevent subsequent errors. After the row address is retired by the host, the DRAM may perform the normal operation (as shown by reference number 318).

In some implementations, an ability to become aware of failed address rows and an ability to retire those address rows may enable transparency to rows with single bit errors that would normally be hidden behind an on-die ECC. The host may have an ability reduce an occurrence of uncorrectable errors due to an accumulation of single bit errors in a DRAM array, which may be important for safety-critical applications like automotive applications. A number of resources that the host has to mitigate page errors may be expanded. A system time to identify and mitigate page errors may be reduced, which may be based on leveraging built-in self-test test patterns. The reduced system time may provide an alternative to lengthy hard repair sequences.

As indicated above, FIG. 3 is provided as an example. Other examples may differ from what is described with regard to FIG. 3.

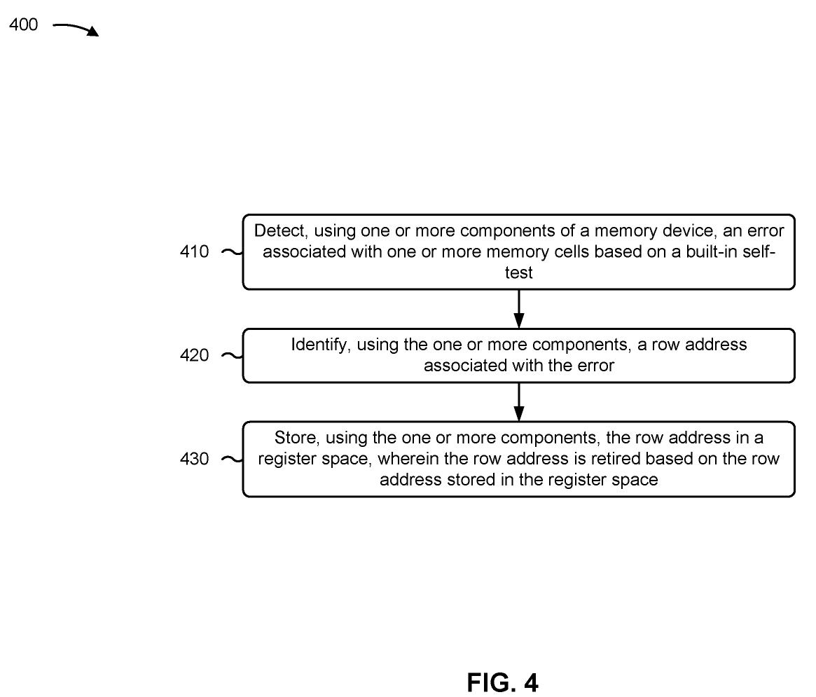

FIG. 4 is a flowchart of an example method 400 associated with built-in self-test for memory devices. In some implementations, a memory device (e.g., the memory device 120) may perform or may be configured to perform the method 400. In some implementations, another device or a group of devices separate from or including the memory device (e.g., the system 100) may perform or may be configured to perform the method 400. Additionally, or alternatively, one or more components of the memory device may perform or may be configured to perform the method 400. Thus, means for performing the method 400 may include the memory device and/or one or more components of the memory device. Additionally, or alternatively, a non-transitory computer-readable medium may store one or more instructions that, when executed by the memory device, cause the memory device to perform the method 400.

As shown in FIG. 4, the method 400 may include detecting, using one or more components of a memory device, an error associated with one or more memory cells based on a built-in self-test (block 410). As further shown in FIG. 4, the method 400 may include identifying, using the one or more components, a row address associated with the error (block 420). As further shown in FIG. 4, the method 400 may include storing, using the one or more components, the row address in a register space, wherein the row address is retired based on the row address stored in the register space (block 430).

The method 400 may include additional aspects, such as any single aspect or any combination of aspects described below and/or described in connection with one or more other methods or operations described elsewhere herein.

In a first aspect, the method 400 includes determining, based on a mode register setting, that a repair sequence associated with the built-in self-test is bypassed, wherein the repair sequence is associated with repairing the row address.

In a second aspect, alone or in combination with the first aspect, the method 400 includes determining whether a repair is available for the row address, wherein the row address is stored in the register space based on the repair not being available for the row address.

In a third aspect, alone or in combination with one or more of the first and second aspects, the method 400 includes resuming a normal operation after the row address is retired, wherein the normal operation is not associated with the built-in self-test.

In a fourth aspect, alone or in combination with one or more of the first through third aspects, the error is associated with a single bit error, and the row address is retired to prevent the row address from becoming associated with an uncorrectable error.

In a fifth aspect, alone or in combination with one or more of the first through fourth aspects, the single bit error is a permanent error based on a physical defect associated with the one or more memory cells.

In a sixth aspect, alone or in combination with one or more of the first through fifth aspects, the row address associated with the error is stored in the register space in accordance with an error reporting, and a mapping of row addresses is based on the error reporting.

In a seventh aspect, alone or in combination with one or more of the first through sixth aspects, the register space is accessible to a host associated with the memory device, and the host is responsible for retiring the row address.

In an eighth aspect, alone or in combination with one or more of the first through seventh aspects, the memory device is associated with DRAM.

Although FIG. 4 shows example blocks of a method 400, in some implementations, the method 400 may include additional blocks, fewer blocks, different blocks, or differently arranged blocks than those depicted in FIG. 4. Additionally, or alternatively, two or more of the blocks of the method 400 may be performed in parallel. The method 400 is an example of one method that may be performed by one or more devices described herein. These one or more devices may perform or may be configured to perform one or more other methods based on operations described herein.

In some implementations, a memory device includes one or more components configured to: detect an error associated with one or more memory cells based on a built-in self-test; identify a row address associated with the error; and store the row address in a register space, wherein the row address is retired based on the row address stored in the register space.

In some implementations, a method includes detecting, using one or more components of a memory device, an error associated with one or more memory cells based on a built-in self-test; identifying, using the one or more components, a row address associated with the error; and storing, using the one or more components, the row address in a register space, wherein the row address is retired based on the row address stored in the register space.

In some implementations, a system includes a memory device configured to: start a built-in self-test; detect an error associated with one or more memory cells based on the built-in self-test; identify a row address associated with the error; and store the row address in a register space, and a host device configured to: read the row address in the register space; and retire the row address based on an inclusion of the row address in the register space.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a + b, a + c, b + c, and a + b + c, as well as any combination with multiples of the same element (e.g., a + a, a + a + a, a + a + b, a + a + c, a + b + b, a + c + c, b + b, b + b + b, b + b + c, c + c, and c + c + c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory device, comprising:
one or more components configured to:
detect an error associated with one or more memory cells based on a built-in self-test;
identify a row address associated with the error; and
store the row address in a register space, wherein the row address is retired based on the row address stored in the register space.

2. The memory device of claim 1, wherein the one or more components are further configured to:
determine, based on a mode register setting, that a repair sequence associated with the built-in self-test is bypassed, wherein the repair sequence is associated with repairing the row address.

3. The memory device of claim 1, wherein the one or more components are further configured to:
determine whether a repair is available for the row address, and wherein the row address is stored in the register space based on the repair not being available for the row address.

4. The memory device of claim 1, wherein the one or more components are further configured to:
resume a normal operation after the row address is retired, wherein the normal operation is not associated with the built-in self-test.

5. The memory device of claim 1, wherein the error is associated with a single bit error, and wherein the row address is retired to prevent the row address from becoming associated with an uncorrectable error.

6. The memory device of claim 5, wherein the single bit error is a permanent error based on a physical defect associated with the one or more memory cells.

7. The memory device of claim 1, wherein the row address associated with the error is stored in the register space in accordance with an error reporting, and wherein a mapping of row addresses is based on the error reporting.

8. The memory device of claim 1, wherein the register space is accessible to a host associated with the memory device, and wherein the host is responsible for retiring the row address.

9. The memory device of claim 1, wherein the memory device is associated with dynamic random access memory (DRAM).

10. A method, comprising:
detecting, using one or more components of a memory device, an error associated with one or more memory cells based on a built-in self-test;
identifying, using the one or more components, a row address associated with the error; and
storing, using the one or more components, the row address in a register space, wherein the row address is retired based on the row address stored in the register space.

11. The method of claim 10, further comprising:
determining, based on a mode register setting, that a repair sequence associated with the built-in self-test is bypassed, wherein the repair sequence is associated with repairing the row address.

12. The method of claim 10, further comprising:
determining whether a repair is available for the row address, wherein the row address is stored in the register space based on the repair not being available for the row address.

13. The method of claim 10, further comprising:
resuming a normal operation after the row address is retired, wherein the normal operation is not associated with the built-in self-test.

14. The method of claim 10, wherein the error is associated with a single bit error, and wherein the row address is retired to prevent the row address from becoming associated with an uncorrectable error.

15. The method of claim 14, wherein the single bit error is a permanent error based on a physical defect associated with the one or more memory cells.

16. The method of claim 10, wherein the row address associated with the error is stored in the register space in accordance with an error reporting, and wherein a mapping of row addresses is based on the error reporting.

17. The method of claim 10, wherein the register space is accessible to a host associated with the memory device, and wherein the host is responsible for retiring the row address.

18. The method of claim 10, wherein the memory device is associated with dynamic random access memory (DRAM).

19. A system, comprising:
a memory device configured to:
start a built-in self-test;
detect an error associated with one or more memory cells based on the built-in self-test;
identify a row address associated with the error; and
store the row address in a register space, and
a host device configured to:
read the row address in the register space; and
retire the row address based on an inclusion of the row address in the register space.

20. The system of claim 19, wherein the memory device is further configured to:
determine, based on a mode register setting, that a repair sequence associated with the built-in self-test is bypassed, wherein the repair sequence is associated with repairing the row address; and
determine whether a repair is available for the row address, wherein the row address is stored in the register space based on the repair not being available for the row address.

21. The system of claim 19, wherein the memory device is further configured to:
resume a normal operation after the row address is retired, wherein the normal operation is not associated with the built-in self-test.

22. The system of claim 19, wherein the error is associated with a single bit error, and wherein the row address is retired to prevent the row address from becoming associated with an uncorrectable error.

23. The system of claim 22, wherein the single bit error is a permanent error based on a physical defect associated with the one or more memory cells.

24. The system of claim 19, wherein the row address associated with the error is stored in the register space in accordance with an error reporting, and wherein a mapping of row addresses is based on the error reporting.

25. The system of claim 19, wherein the memory device is associated with dynamic random access memory (DRAM).
